(19) United States
(12) Patent Application Publication
(10) Pub. No.: US 2024/0171865 A1
(43) Pub. Date: May 23, 2024

(54) METHOD OF GENERATING AN IMAGE OF A PATTERN ON A WORKPIECE

(71) Applicant: TASMIT, Inc., Kanagawa (JP)

(72) Inventor: Koji KANEKO, Kanagawa (JP)

(21) Appl. No.: 18/284,228

(22) PCT Filed: Mar. 17, 2022
(86) PCT No.: PCT/JP2022/012175

§ 371 Date: Sep. 26, 2023

(30) Foreign Application Priority Data
Mar. 30, 2021 (JP) 2021-056705

(51) Int. Cl. H04N 23/76; G06T 7/60

(52) U.S. Cl. CPC H04N 23/76; G06T 7/60; G06T 2207/10061; G06T 2207/10152; G06T 2207/30164

(57) ABSTRACT

The method includes: determining a reference area in a surface of the workpiece; calculating a pattern density of the reference area from design data for patterns in the reference area; determining adjustment areas having pattern densities that approximate the calculated pattern density within a predetermined range; generating an image of the reference area with a scanning electron microscope; generating an image of one of the adjustment areas with the scanning electron microscope; adjusting set values of parameters for adjusting the brightness of the image of the one adjustment area so as to reduce a difference between a brightness histogram of the image of the one adjustment area and a brightness histogram of the image of the reference area; and generating images of intermediate areas in the surface of the workpiece with the scanning electron microscope.

### TECHNICAL FIELD

The present invention relates to a method of generating an image of a pattern formed on a workpiece, such as a wafer, a substrate, a panel, a mask, etc., with a scanning electron microscope, and more particularly to a technique for continuously generating multiple images while adjusting brightness of the images.

### BACKGROUND ART

In inspection and measurement using an electron microscope, brightness adjustment is very important for stabilizing results of the inspection and the measurement. For example, in a die-to-die inspection, the brightness may affect a sensitivity for defect detection. In a measuring process called CD-SEM, length measurement values may not be stable when a minimum brightness and a maximum brightness are saturated.

During long-term inspection and measurement, the brightness may change due to factors including sample charging, a change in condition of layered films, and charging of the electron microscope itself. Therefore, the brightness is adjusted at a preset time or at a preset location in a sample in order to suppress the influence of the change in brightness on inspection and measurement results.

### CITATION LIST

### Patent Literature

Patent document 1: Japanese laid-open patent publication No. 4-328234

### SUMMARY OF INVENTION

### Technical Problem

Most of conventional mechanisms for automatically adjusting the brightness involve performing beam irradiation on a narrow area set in advance, and adjusting the brightness based on a histogram of an image obtained. However, there is a sample whose electron emission efficiency is likely to change due to beam irradiation. In such a sample, the brightness may change with each beam irradiation, which may adversely affect the results of inspection and measurement. In addition, the change in brightness may be affected by a beam irradiation history around an imaging position. As a result, correct brightness adjustment may not be achieved if the brightness is adjusted at a location distant from the imaging position.

A brightness of an image varies greatly depending on a line width and density of target patterns. For example, an image with a low pattern density has a high brightness, while an image with a high pattern density has a low brightness. Therefore, it is not possible to achieve stable brightness adjustment by the brightness adjustment in areas with different pattern densities.

A time consumed in the beam irradiation for the purpose of the brightness adjustment, not for the purpose of inspection and measurement, is an additional time other than the inspection and measurement, which reduces a throughput. Especially in a case of scanning large areas with an electron microscope, the throughput is greatly reduced.

Accordingly, the present invention provides an image generation method capable of appropriately adjusting a brightness without lowering a throughput.

### Solution to Problem

In an embodiment, there is provided a method of generating an image of a workpiece having a patterned surface while adjusting a brightness of the image, comprising: determining a reference area in a surface of the workpiece; calculating a pattern density of the reference area from design data for patterns in the reference area; determining adjustment areas having pattern densities that approximate the calculated pattern density within a predetermined range; generating an image of the reference area with a scanning electron microscope; generating an image of one of the adjustment areas with the scanning electron microscope; adjusting set values of parameters for adjusting the brightness of the image of the one adjustment area so as to reduce a difference between a brightness histogram of the image of the one adjustment area and a brightness histogram of the image of the reference area; and generating images of intermediate areas in the surface of the workpiece with the scanning electron microscope.

In an embodiment, the parameters include an analog parameter for determining electron detection sensitivity of the scanning electron microscope and a digital parameter for adjusting brightness via image processing, and the method further comprises: after adjusting a set value of the analog parameter, applying the adjusted set value of the analog parameter to the scanning electron microscope; and adjusting brightness of the images of the intermediate areas by applying the adjusted set value of the digital parameter to image processing on the images of the intermediate areas.

In an embodiment, the method further comprises repeating operations from generating of an image of one of the adjustment areas with the scanning electron microscope to adjusting of brightness of images of intermediate areas.

In an embodiment, the pattern density is defined by a relationship between widths and lengths of corresponding CAD patterns.

### Advantageous Effects of Invention

The adjustment areas are selected such that the pattern density in each adjustment area is close to the pattern density in the reference area. Therefore, parameter adjustment in each adjustment area can be substituted for parameter adjustment in the reference area. According to the present invention, it is not necessary to generate an image of the reference area every time the brightness is adjusted. In other words, the brightness can be adjusted in the adjustment areas included in the target areas while generating images of multiple target areas including the adjustment areas and the intermediate areas. As a result, images of the target areas with stable brightness can be generated without a decrease in a throughput of the image generation of a large number of target areas including the adjustment areas and the intermediate areas.

### BRIEF DESCRIPTION OF DRAWINGS

FIG. 1 is a schematic diagram showing an embodiment of an image generating apparatus;

FIG. 2 is a schematic diagram illustrating an embodiment of calculating a pattern density in a reference area;

FIG. 3 is a schematic diagram illustrating another embodiment of calculating the pattern density in the reference area;

FIG. 4 is a flow chart describing an embodiment of setting the reference area and a plurality of adjustment areas;

FIG. 5 is a flow chart describing an embodiment of operations for generating images;

FIG. 6 is a diagram showing an example of a brightness histogram;

FIG. 7A is a histogram showing an example in which an entire mound is biased toward a low brightness side;

FIG. 7B is a histogram showing an example in which an entire mound is biased toward a high brightness side;

FIG. 8A is a histogram of brightness to illustrate an embodiment of adjusting analog parameter and digital parameter;

FIG. 8B is a histogram of brightness to illustrate an embodiment of adjusting analog parameter and digital parameter; and

FIG. 8C is a histogram of brightness to illustrate an embodiment of adjusting analog parameter and digital parameter.

### DESCRIPTION OF EMBODIMENTS

Hereinafter, embodiments of the present invention will be described with reference to the drawings.

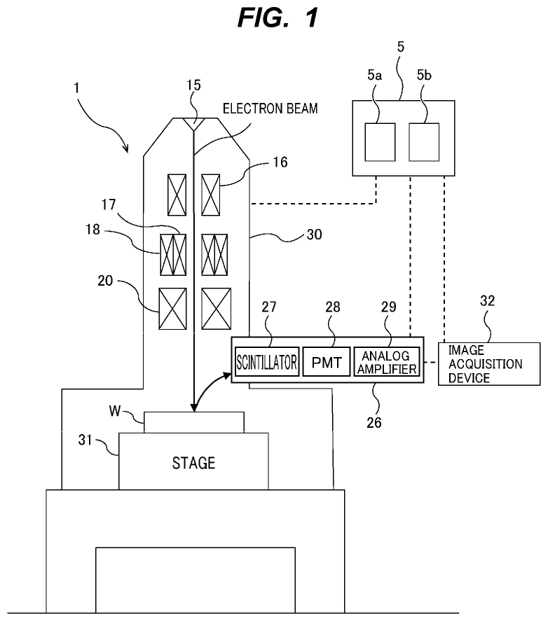

FIG. 1 is a schematic diagram showing an embodiment of an image generating apparatus. The image generating apparatus includes a scanning electron microscope 1 configured to generate an image of a workpiece W, and an operation controller 5 configured to control operations of the scanning electron microscope 1. Examples of workpiece W include wafer, mask, panel, substrate, etc., which are used in manufacturing of semiconductor devices.

The operation controller 5 is composed of at least one computer. The operation controller 5 includes a memory 5a storing programs therein, and a processor 5b configured to execute arithmetic operations according to instructions included in the programs. The memory 5a includes a main memory, such as a random access memory (RAM), and an auxiliary memory, such as a hard disk drive (HDD) or solid state drive (SSD). Examples of the processor 5b include a CPU (central processing unit) and a GPU (graphic processing unit). However, the specific configurations of the operation controller 5 are not limited to these examples.

The scanning electron microscope 1 has an electron gun 15 configured to emit an electron beam, a converging lens 16 configured to converge the electron beam emitted from the electron gun 15, an X deflector 17 configured to deflect the electron beam in an X direction, a Y deflector 18 configured to deflect the electron beam in a Y direction, an objective lens 20 configured to focus the electron beam on the workpiece W, and a stage 31 configured to support the workpiece W. The electron gun 15, the converging lens 16, the X deflector 17, the Y deflector 18, and the objective lens 20 are arranged in a column 30.

The electron beam emitted from the electron gun 15 is converged by the converging lens 16, and is then focused by the objective lens 20 onto a surface of the workpiece W, while the electron beam is deflected by the X deflector 17 and the Y deflector 18. When the workpiece W is irradiated with primary electrons of the electron beam, the workpiece W emits electrons, such as secondary electrons and backscattered electrons. The electrons emitted from the workpiece W are detected by an electron detector 26.

The electron detector 26 includes a scintillator 27 configured to convert the electrons (the secondary electrons or the backscattered electrons) emitted from the workpiece W into light, and a photomultiplier tube (PMT) 28 configured to convert the light, converted by the scintillator 27, into an electrical signal, and an analog amplifier 29 configured to amplify the electrical signal output from the photomultiplier tube 28. The electrons (the secondary electrons or the backscattered electrons) emitted from the workpiece W are detected by the electron detector 26 including the scintillator 27, the photomultiplier tube 28, and the analog amplifier 29. The electrical signal output from the electron detector 26 is input to an image acquisition device 32, which converts the electrical signal into an image. In this way, the scanning electron microscope 1 generates an image of the surface of the workpiece W. The image acquisition device 32 is coupled to the operation controller 5.

The image generating apparatus has a function of adjusting a brightness of the image generated by the scanning electron microscope 1. The brightness adjustment will be described in detail below. Parameters for adjusting the brightness of the image (which may be hereinafter referred to as brightness parameters) include analog parameters and digital parameters. The analog parameters are applied to the electron detector 26 which is configured to detect the electrons (the secondary electrons or the backscattered electrons) emitted from the workpiece W. The digital parameters are applies to digital processing on the image generated by the scanning electron microscope 1. Specifically, the analog parameters are applied when the scanning electron microscope 1 generates the image, and the digital parameters are applied to the image processing on the image that has been generated by the scanning electron microscope 1.

The analog parameters are parameters that determine electron detection sensitivity of the scanning electron microscope 1. More specifically, the analog parameters are those for adjusting the electrical signal output from electron detector 26. These analog parameters include a PMT gain for adjusting a level of the electrical signal output from the photomultiplier tube 28, an analog gain for adjusting a level of the electrical signal output from the analog amplifier 29, and an analog offset for shifting a position of a peak of the electrical signal, output from the analog amplifier 29, along brightness values.

The PMT gain is a parameter for changing an amplification ratio when converting the incident light into the electrical signal. When the PMT gain is increased, the incident light is converted into a stronger electrical signal. The analog gain and the analog offset are parameters for adjusting operations of the analog amplifier 29. When the analog gain is increased, the peak of the electrical signal is lowered, while the strength of the electrical signal becomes more uniform over an entire brightness range. When the analog offset is increased, the position of the peak of the electrical signal moves to the high brightness side.

The digital parameters are parameters for adjusting the brightness via the image processing. The digital parameters include a digital gain and a digital offset. The image processing is performed on the image by the operation controller 5. The digital gain is a parameter for changing an overall distribution of the brightness of all pixels forming the image. When the digital gain is increased, a peak of the brightness of the image is lowered, while the brightness of all pixels forming the image becomes more uniform. The digital offset is a parameter for shifting a position of the peak of the brightness of the entire image along brightness values. When the digital offset is increased, the position of the peak of the brightness of the entire image moves to the high brightness side.

In this embodiment, the five brightness parameters, i.e., the PMT parameter, the analog gain, the analog offset, the digital gain, and the digital offset are used to adjust the brightness of the image. However, the present invention is not limited to this embodiment, and only one of the five brightness parameters described above may be used, or a parameter other than the five brightness parameters may be further used. A plurality of electron detectors or different detection methods may be combined, and independent parameters may be used.

When many images are being generated, the brightness of each image may change due to factors, such as the electrical charge of the workpiece W and/or the electrical charge of the scanning electron microscope 1 itself. Therefore, in order to compensate for such a change in brightness over time, the image generating apparatus is configured to adjust the brightness of each of images while continuously generating the images of multiple target areas on the workpiece W. More specifically, the image generating apparatus is configured to adjust the brightness at intervals while generating the images of the multiple target areas on the workpiece W. The intervals of the brightness adjustment are either time intervals or distance intervals on the workpiece W. By periodically adjusting the brightness while generating the images, the image generating apparatus can compensate for a change in brightness over time.

The brightness adjustment is performed in multiple areas having the same or similar pattern density. These multiple areas include one reference area and a plurality of adjustment areas. The reference area is an area used to determine initial values of the above-discussed brightness parameters (i.e., the PMT parameters, the analog gain, the analog offset, the digital gain, and the digital offset) used for the brightness adjustment. Each of the adjustment areas is an area having a pattern density similar to the pattern density in the reference area within a predetermined range. The pattern density will be described later.

The reference area and the plurality of adjustment areas where the brightness adjustment is performed are included in the multiple target areas which are objects of images to be generated. The reference area and the plurality of adjustment areas are predetermined prior to generating of the images of the multiple target areas on the workpiece W. In one embodiment, the reference area and the plurality of adjustment areas may be determined while the images of the multiple target areas on the workpiece W are being generated. The operation controller 5 stores, in its memory 5a, positions and sizes of the reference area and the plurality of adjustment areas that have been determined.

Each adjustment area is an area having a pattern density that approximates the pattern density of the reference area. The pattern density is defined by a relationship between widths and lengths of CAD patterns corresponding to patterns within each area. More specifically, the pattern density is calculated from the widths and lengths of the corresponding CAD patterns. Each CAD pattern is a virtual pattern defined by pattern design information included in design data for patterns formed on the workpiece W. Each CAD pattern has a polygonal shape. The patterns are formed on the workpiece W according to the CAD patterns on the design data. The design data for the patterns formed on the workpiece W is stored in advance in the memory 5a of the operation controller 5.

The operation controller 5 calculates the pattern density of the reference area from the design data for patterns in the reference area. Similarly, the operation controller 5 calculates the pattern density of each of the target areas on the workpiece W to be imaged from the design data for patterns in each target area.

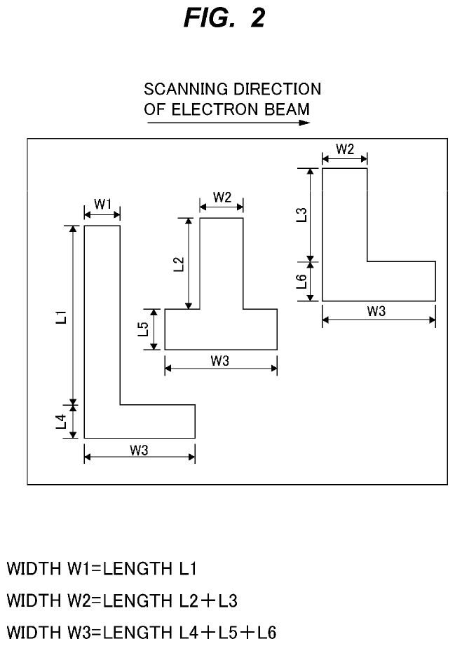

FIG. 2 is a schematic diagram illustrating an embodiment of calculating the pattern density in the reference area on the workpiece W. In this example, there are three patterns in the reference area. Three patterns shown in FIG. 2 are CAD patterns corresponding to the three patterns in the reference area. The operation controller 5 calculates the pattern density of the reference area from the design data. More specifically, the operation controller 5 calculates the pattern density of the reference area from dimensions of the corresponding CAD patterns on the design data. In the example shown in FIG. 2, a dimension along a scanning direction of the electron beam is defined as width, and a dimension along a direction perpendicular to the scanning direction of the electron beam is defined as length. As shown in FIG. 2, the three CAD patterns include portions with three widths W1, W2, W3. A total length of portions having the width W1 is L1, a total length of portions having the width W2 is L2+L3, and a total length of portions having the width W3 is L4+L5+L6. The pattern density of the reference area is expressed as the relationship between the widths W1, W2, W3 and the corresponding lengths L1, L2+L3, L4+L5+L6 of the three CAD patterns corresponding to the patterns in the reference area.

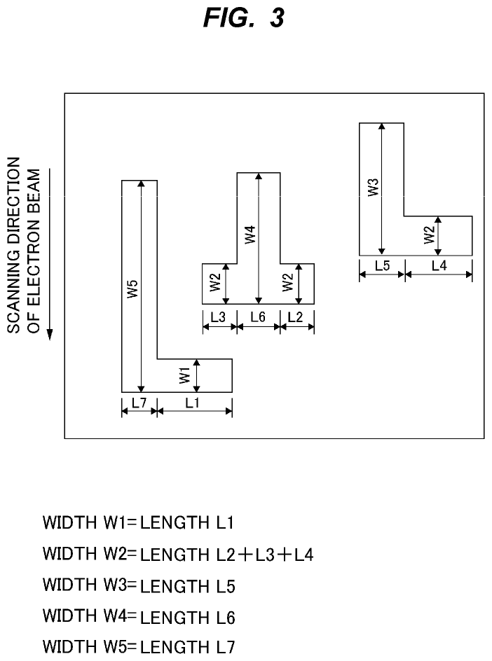

FIG. 3 is a schematic diagram illustrating another embodiment of calculating the pattern density in the reference area on the workpiece W. Three CAD patterns shown in FIG. 3 are the same as the three CAD patterns shown in FIG. 2, but the scanning direction of the electron beam is different from that in FIG. 2 by 90°. As shown in FIG. 3, the three CAD patterns include portions with widths W1, W2, W3, W4, W5. A total length of portions having the width W1 is L1, a total length of portions having the width W2 is L2+L3+L4, a total length of portions having the width W3 is L5, a total length of portions having the width W4 is L6, and a total length of portions having the width W5 is L7. The pattern density of the reference area is expressed as the relationship between the widths W1, W2, W3, W4, W5 and the corresponding lengths L1, L2+L3+L4, L5, L6, L7 of the three CAD patterns corresponding to the patterns in the reference area.

The operation controller 5 calculates pattern densities of areas in the target areas other than the reference area in the same way. Furthermore, the operation controller 5 determines the plurality of adjustment areas having pattern densities that approximate the pattern density of the reference area within a predetermined range. More specifically, the operation controller 5 compares the pattern density of the reference area with a pattern density of each of the target areas, selects from the target areas a plurality of areas having pattern densities that approximate the pattern density of the reference area within the predetermined range, and determines the adjustment areas which are the plurality of areas selected. Each adjustment area is an area where the brightness adjustment is performed. In an embodiment, the predetermined range used to determine the similarity of the pattern density is a numerical range centered on the pattern density of the reference area (i.e., centered on the widths and lengths of the CAD patterns in the reference area).

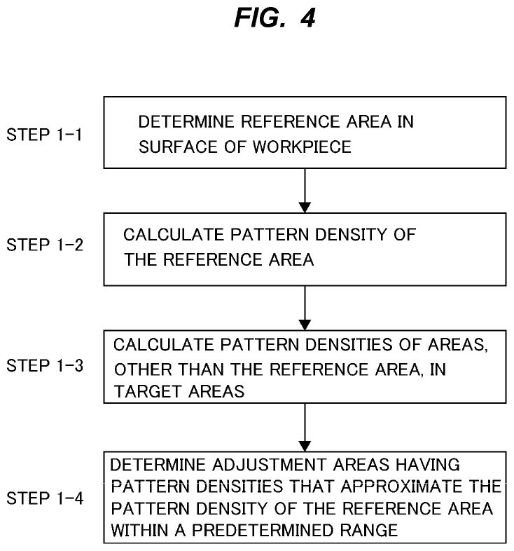

FIG. 4 is a flow chart describing an embodiment of a process of setting the reference area and the plurality of adjustment areas.

In step 1-1, the reference area in the surface of the workpiece W is determined. The determination of the reference area may be performed by a user or may be performed by the operation controller 5. The operation controller 5 stores, in its memory 5a, the position and size of the determined reference area. The position and size of the reference area can be specified from the design data for patterns.

In step 1-2, the operation controller 5 calculates the pattern density of the reference area.

In step 1-3, the operation controller 5 calculates pattern densities of areas, other than the reference area, in the target areas.

In step 1-4, the operation controller 5 compares the pattern density of the reference area with the pattern densities of the other areas and determines the plurality of adjustment areas having pattern densities that approximate the pattern density of the reference area within the predetermined range. The operation controller 5 stores, in its memory 5a, positions and sizes of the plurality of adjustment areas determined. The positions and sizes of the plurality of adjustment areas can be specified from the design data for patterns.

In this way, the reference area and the plurality of adjustment areas for the brightness adjustment are determined. The operation controller 5 then instructs the scanning electron microscope 1 to generate images of the multiple target areas including the reference area, the plurality of adjustment areas, and intermediate areas (which will be discussed later). In an embodiment, while the scanning electron microscope 1 is generating the images of the multiple target areas, the operation controller 5 may determine the reference area and the plurality of adjustment areas.

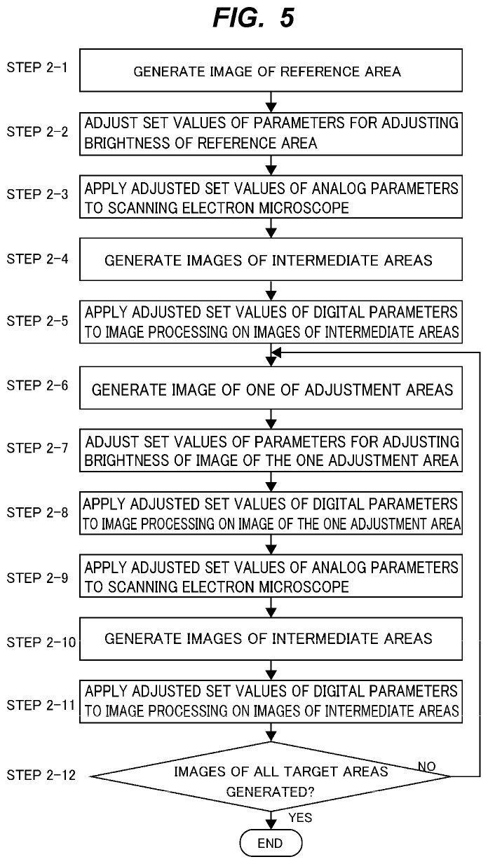

The operation of generating images will be described below with reference to a flowchart shown in FIG. 5.

In step 2-1, the operation controller 5 instructs the scanning electron microscope 1 to generate the image of the reference area.

In step 2-2, the operation controller 5 receives the image of the reference area from the scanning electron microscope 1 and adjusts set values of the parameters for adjusting the brightness of the image of the reference area. In this embodiment, the parameters are the above-discussed five brightness parameters (i.e., the PMT parameter, the analog gain, the analog offset, the digital gain, and the digital offset). The set values of the parameters adjusted in the step 2-2 are the initial values of the parameters. In an embodiment, the set values of the parameters for adjusting the brightness of the image of the reference area may be adjusted by a user.

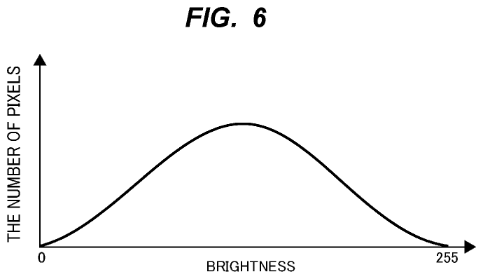

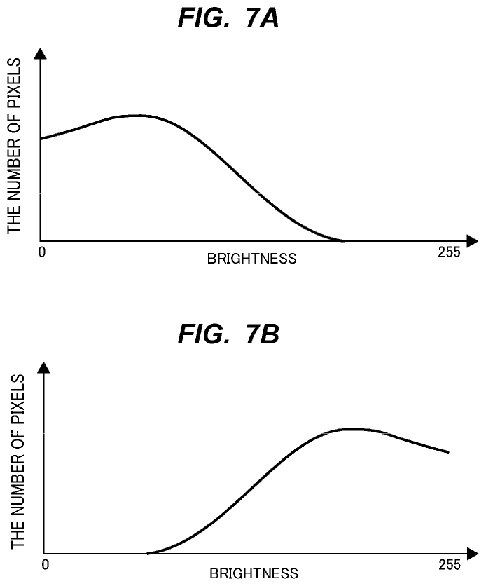

The brightness of the entire image is represented by a brightness histogram. The brightness histogram is a graph having a horizontal axis representing brightness and a vertical axis representing the number of pixels having each brightness. FIG. 6 is a diagram showing an example of the brightness histogram. In a grayscale image, the brightness on the horizontal axis is expressed by numerical values from 0 to 255, for example. This numerical range of brightness from 0 to 255 is an example, and other numerical range may be used. In general, as shown in FIG. 6, a preferable brightness adjustment is such that one end of a mound foot of the histogram is at the minimum value of brightness (0 in the example of FIG. 6) and the other end is at the maximum value of brightness (255 in the example of FIG. 6). On the other hand, as shown in FIG. 7A, when the entire mound of the histogram is biased toward the low-brightness side, and the left end of the foot of the mound does not appear on the histogram, the image is dark and many black crushes appear in the image. In another example, as shown in FIG. 7B, when the entire mound of the histogram is biased toward the high brightness side, and the right end of the foot of the mound does not appear on the histogram, the image is bright and has many blown-out highlights. Therefore, the brightness adjustment is performed such that the histogram has a mound shape as shown in FIG. 6.

Referring back to FIG. 5, in step 2-3, among the above five parameters, the adjusted set values of the PMT parameter, the analog gain, and the analog offset, which are the analog parameters, are applied to the scanning electron microscope 1.

In step 2-4, the operation controller 5 instructs the scanning electron microscope 1 to continuously generate a plurality of images of a plurality of intermediate areas. The plurality of intermediate areas are areas which are included in the target areas and are other than the reference area and the plurality of adjustment areas. The number of intermediate areas may be determined based on the time intervals or the distance intervals required for the brightness adjustment.

In step 2-5, the operation controller 5 applies the adjusted set values of the digital parameters, i.e., the digital gain and the digital offset, among the five brightness parameters, to image processing on the plurality of images of the plurality of intermediate areas generated in the step 2-4. As described above, the digital parameters are parameters for adjusting the brightness of the image via the image processing. Therefore, the operation controller 5 can adjust the brightness of the generated image using the digital parameters. The images whose brightness has been adjusted by the digital parameters are stored in the memory 5a of the operation controller 5. In step 2-6, the operation controller 5 instructs the scanning electron microscope 1 to generate an image of one of the plurality of adjustment areas.

In step 2-7, the operation controller 5 receives the image of the one adjustment area from the scanning electron microscope 1 and adjusts the set values of the parameters for adjusting the brightness of the image of the one adjustment area so as to reduce a difference between the brightness histogram of the image of the one adjustment area and the brightness histogram of the image of the reference area. Specifically, the operation controller 5 adjusts the set values of the parameters such that the mound shape of the brightness histogram of the image of the one adjustment area approaches the mound shape of the brightness histogram of the image of the reference area. In this embodiment, the parameters are the five brightness parameters described above (i.e., the PMT parameter, the analog gain, the analog offset, the digital gain, and the digital offset).

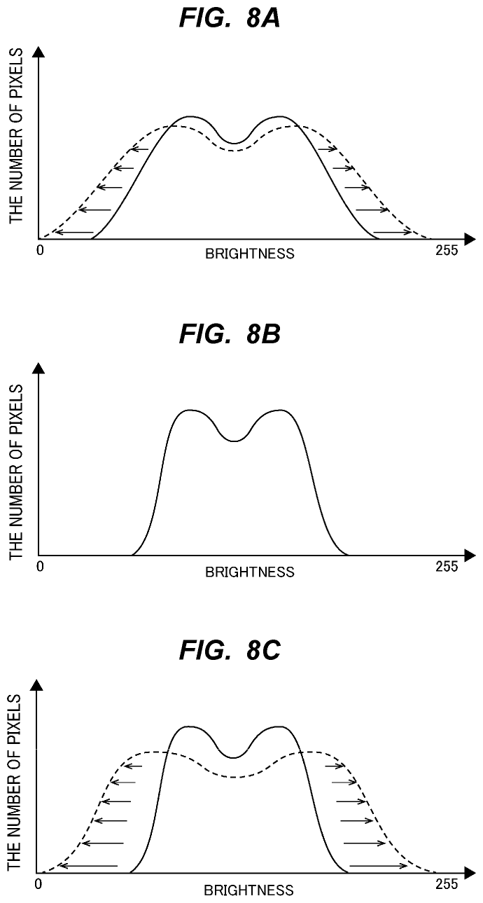

An embodiment of the step 2-7 will be described with reference to FIGS. 8A to 8C. In an embodiment, the scanning electron microscope 1 repeatedly generates an image of the same area of the workpiece W to generate a plurality of images. The operation controller 5 integrates or adds up these images and generates an average image by dividing a brightness value of each pixel of the integrated images by the number of integrated images.

FIG. 8A is a diagram showing a brightness histogram of one of the plurality of images before being integrated. Of the five brightness parameters described above, the analog parameters are applied to each of the plurality of images before being integrated. Specifically, as indicated by a dotted line in FIG. 8A, the operation controller 5 adjusts the analog parameters so as to widen a brightness range (i.e., increase a contrast of the image) as long as the brightness does not saturate at the low brightness side and the high brightness side.

FIG. 8B is a diagram showing a brightness histogram of the average image obtained by integrating the plurality of images of the same area and further dividing the brightness value of each pixel of the integrated images by the number of integrated images. As can be seen from FIG. 8B, since the integrated brightness value of each pixel is divided by the number of integrated images, random noises are removed from the average image, so that an SN ratio of the average image is improved. On the other hand, the brightness range of the average image is narrowed (i.e., the contrast of the average image is lowered).

Therefore, as shown in FIG. 8C, the operation controller 5 applies the digital parameters among the above-described five brightness parameters to the average image to widen the brightness range (or increase the contrast of the average image). Specifically, the operation controller 5 adjusts the set values of the digital parameters such that the shape of the histogram in FIG. 8C approaches the brightness histogram of the image of the reference area indicated by a dotted line.

Referring back to FIG. 5, in step 2-8, the operation controller 5 applies the adjusted set values of the digital parameters (i.e., the digital gain and the digital offset) among the above-discussed five parameters to the image processing on the image of the adjustment area generated in the step 2-6. The image whose brightness has been adjusted by the digital parameters is stored in the memory 5a of the operation controller 5.

In step 2-9, the operation controller 5 applies the adjusted set values of the analog parameters (i.e., the PMT parameter, the analog gain, and the analog offset) among the above-discussed five parameters to the scanning electron microscope 1. These analog parameters are applied to the scanning electron microscope 1 before generating a next image.

In step 2-10, the operation controller 5 instructs the scanning electron microscope 1 to continuously generate a plurality of images of a plurality of other intermediate areas. The plurality of other intermediate areas in the step 2-10 are also included in the target areas. The number of intermediate areas may be determined based on the time intervals or the distance intervals required for the brightness adjustment.

In step 2-11, the operation controller 5 applies the set values of the digital gain and the digital offset, which are the digital parameters adjusted in the step 2-7, to image processing on the plurality of other intermediate areas generated in the step 2-10. The brightness of each image of the plurality of other intermediate areas is adjusted by the digital parameters. The images whose brightness has been adjusted by the digital parameters are stored in the memory 5a of the operation controller 5.

In step 2-12, the operation controller 5 determines whether images of all target areas have been generated. If images of all the target areas have not been generated, the operation controller 5 repeats the step 2-6 and the subsequent steps. When the images of all the target areas have been generated, the operation controller 5 instructs the scanning electron microscope 1 to terminate the generation of the images of the target areas.

The pattern density in each adjustment area is close to the pattern density in the reference area. Therefore, the parameter adjustment in each adjustment area can be substituted for the parameter adjustment in the reference area. According to the embodiments, it is not necessary to generate an image of the reference area every time the brightness is adjusted. In other words, while the scanning electron microscope 1 generates the images of the multiple target areas including the adjustment areas and the intermediate areas, the operation controller 5 can adjust the brightness in the adjustment areas included in the target areas. As a result, the throughput of imaging the multiple target areas, including the adjustment areas and the intermediate areas, can be increased.

For the sake of simplifying the explanations, each image in the above-described embodiments is assumed to be an image of patterns of the workpiece in which only one layer on the surface is resolved. It should be noted that the above-discussed brightness adjustment technique can be applied, with use of design data of multiple layers, to an image of patterns in the multiple layers that has been generated with accelerated primary electrons. The number of electrons reaching the electron detector may decrease in a lower layer, and the effect of brightness on the detected image may decrease. In such a case, the pattern density for each layer calculated from the design value may be multiplied by a certain ratio so as to match the actually detected image. There are various types of electron detectors, such as a detector configured to mainly detect the secondary electrons and a detector configured to mainly detect backscattered electrons. There is a difference in the effect of brightness of each layer on the detected image between the types of electron detectors. Therefore, a contribution ratio of each layer according to a type of electron detector may be used.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

### INDUSTRIAL APPLICABILITY

The present invention is applicable to a method of generating an image of a pattern formed on a workpiece, such as a wafer, a substrate, a panel, a mask, etc., with a scanning electron microscope.

### REFERENCE SIGNS LIST

1 scanning electron microscope
5 operation controller
15 electron gun
16 converging lens
17 X deflector
18 Y deflector
20 objective lens
26 electron detector
27 scintillator
28 photomultiplier tube
29 analog amplifier
30 column
31 stage
32 image acquisition device

1. A method of generating an image of a workpiece having a patterned surface while adjusting a brightness of the image, comprising:
determining a reference area in a surface of the workpiece;
calculating a pattern density of the reference area from design data for patterns in the reference area;
determining adjustment areas having pattern densities that approximate the calculated pattern density within a predetermined range;
generating an image of the reference area with a scanning electron microscope;
generating an image of one of the adjustment areas with the scanning electron microscope;
adjusting set values of parameters for adjusting the brightness of the image of the one adjustment area so as to reduce a difference between a brightness histogram of the image of the one adjustment area and a brightness histogram of the image of the reference area; and
generating images of intermediate areas in the surface of the workpiece with the scanning electron microscope.

2. The method according to claim 1, wherein the parameters include an analog parameter for determining electron detection sensitivity of the scanning electron microscope and a digital parameter for adjusting brightness via image processing, and
the method further comprises:
after adjusting a set value of the analog parameter, applying the adjusted set value of the analog parameter to the scanning electron microscope; and
adjusting brightness of the images of the intermediate areas by applying the adjusted set value of the digital parameter to image processing on the images of the intermediate areas.

3. The method according to claim 2, further comprising:
repeating operations from generating of an image of one of the adjustment areas with the scanning electron microscope to adjusting of brightness of images of intermediate areas.

4. The method according to claim 1, wherein the pattern density is defined by a relationship between widths and lengths of corresponding CAD patterns.
